(19) United States
(12) Patent Application Publication
(10) Pub. No.: US 2025/0323606 A1
(43) Pub. Date: Oct. 16, 2025

(54) HIGH-LINEARITY TWO-STAGE COMPLEMENTARY AMPLIFIER

(71) Applicant: Realtek Semiconductor Corp., Hsinchu (TW)

(72) Inventors: Poh Boon Leong, Pleasanton, CA (US); Chia-Liang (Leon) Lin, Fremont, CA (US)

(21) Appl. No.: 18/633,629

(22) Filed: Apr. 12, 2024

(51) Int. Cl. H03F 1/32; H03F 3/16

(52) U.S. Cl. CPC H03F 1/32; H03F 3/16

(57) ABSTRACT

A two-stage complementary amplifier (TSCA) includes a common-source input stage comprising a stack-up of a n-type common-source amplifier and a p-type common-source amplifier configured to receive a first signal and a second signal and output a third signal and a fourth signal across a first inductor and a second inductor, respectively; a common-gate output stage having a stack-up of a n-type common-gate amplifier and a p-type common-gate amplifier configured to receive the third signal and the fourth signal via a first capacitor and a second capacitor, respectively, and output a fifth signal and a sixth signal across a third inductor and a fourth inductor, respectively; and a fifth inductor terminated with a load, wherein the third inductor, the fourth inductor, and the fifth inductor are laid out tightly and substantially parallel to have strong mutual coupling.

### BACKGROUND OF THE INVENTION

### Field of the Invention

The present invention generally relates to amplifiers and more particularly to amplifiers having a two-stage complementary topology.

### Description of Related Art

A MOST (metal-oxide semiconductor field-effect transistor) is an active device having a source, a gate, and a drain, and can be used to embody an amplifier. A MOST can be either a NMOST (n-channel metal-oxide semiconductor field-effect transistor) or a PMOST transistor (p-channel metal-oxide semiconductor field-effect transistor). A MOST has a threshold voltage. The MOST is in a “saturation region” and can function effectively as an amplifier when a gate-to-source voltage is larger than the threshold voltage but a gate-to-drain voltage is smaller than the threshold voltage. The MOST is in a “triode region” and can function effectively as a switch when the gate-to-source voltage and the gate-to-drain voltage are both larger than the threshold voltage.

A MOST can be configured as a common-source amplifier that converts an input voltage received from its gate into an output current delivered via its drain, while its source is connected to a sufficiently low-impedance node so that a voltage at its source can remain substantially fixed regardless of a dynamic nature of the input voltage. An incremental change in the input voltage will result in an incremental change in the output current, and a ratio between the latter and the former is known as the “transconductance,” which quantifies how effective the common-source amplifier performs the input voltage to output current conversion. The transconductance will be reduced in the presence of “source degeneration,” wherein the impedance at the source is not sufficiently low. The linearity of a common-source amplifier is gauged by how well the transconductance can maintain substantially the same as a swing of the input voltage increases. To maintain good linearity, the MOST must remain in the “saturation region” for as large a swing of the input voltage as possible.

A MOST can also be configured as a common-gate amplifier that receives an input current from its source and delivers an output current via its drain, while its gate is connected to a sufficiently low-impedance node so that a voltage at its gate can remain substantially fixed regardless of a dynamic nature of the input current. A common-gate amplifier can effectively direct the input current into the output current, such that an incremental change in the input current can lead to a substantially equal incremental change in the output current.

A second MOST can be stacked onto a first MOST of the same type in a “cascode” topology, wherein the second MOST and the first MOST share the same current path, and an output current of the first MOST becomes an input current of the second MOST. A benefit of the cascode topology is to provide a good reverse isolation, such that a change in a loading condition seen at the drain of the second MOST has little effect on the first MOST.

U.S. Pat. No. 10,447,218 discloses an amplifier based on using a combination of a NMOST and a PMOST configured in a hybrid differential common-source topology. The amplifier disclosed therein can effectively mitigate adverse effects of undesired source degeneration (resulting from the nonzero impedance of the source node) that often exists in a practical embodiment of a conventional common-source amplifier, but it also suffers linearity degradation when a large input voltage causes the NMOST and the PMOST to enter the “triode” region.

What is desired, however, is an amplifier that can maintain good linearity even when the NMOST and the PMOST enter the “triode” region.

### BRIEF SUMMARY OF THIS INVENTION

In an embodiment, a two-stage complementary amplifier (TSCA) comprises: a common-source input stage comprising a stack-up of a n-type common-source amplifier (NCSA) and a p-type common-source amplifier (PCSA) configured to receive a first signal and a second signal and output a third signal and a fourth signal across a first inductor and a second inductor, respectively, wherein the NCSA comprises a stack-up of a first NMOST (n-channel metal-oxide semiconductor field-effect transistor) and a second NMOST configured in common-source topology and cascode topology, respectively, while the PCSA comprises a stack-up of a first PMOST (p-channel metal-oxide semiconductor field-effect transistor) and a second PMOST configured in common-source topology and cascode topology, respectively; a common-gate output stage comprising a stack-up of a n-type common-gate amplifier (NCGA) and a p-type common-gate amplifier (PCGA) configured to receive the third signal and the fourth signal via a first capacitor and a second capacitor, respectively, and output a fifth signal and a sixth signal across a third inductor and a fourth inductor, respectively, wherein the NCGA comprising a stack-up of a third NMOST and a fourth NMOST configured in common-gate topology and cascode topology, respectively, while the PCGA comprising a stack-up of a third PMOST and a fourth PMOST configured in common-gate topology and cascode topology, respectively; and a fifth inductor terminated with a load, wherein the third inductor, the fourth inductor, and the fifth inductor are laid out tightly and substantially in parallel to have strong mutual coupling.

### BRIEF DESCRIPTION OF THE DRAWINGS

FIG. 1 shows a schematic diagram of a two-stage complementary amplifier in accordance with an embodiment of the present disclosure.

FIG. 2 shows a top view of an exemplary layout of three inductors used in the two-stage complementary amplifier of FIG. 1.

### DETAILED DESCRIPTION OF THIS INVENTION

The present invention relates to amplifiers. While the specification describes several example embodiments of the invention considered favorable modes of practicing the invention, it should be understood that the invention can be implemented in many ways and is not limited to the particular examples described below or to the particular manner in which any features of such examples are implemented. In other instances, well-known details are not shown or described to avoid obscuring aspects of the invention.

Persons of ordinary skill in the art understand terms and basic concepts related to microelectronics that are used in this disclosure, such as “voltage,” “current,” “signal,” “differential signal,” “capacitor,” “inductor,” “resistor,” “transistor,” “MOST (metal-oxide semiconductor field-effect transistor),” “PMOST (p-channel metal oxide semiconductor field-effect transistor),” “NMOST (n-channel metal oxide semiconductor field-effect transistor),” “AC (alternating current),” “DC (direct current),” “source,” “gate,” “drain,” “node,” “ground node,” “power supply node,” “cascode,” “amplifier,” “common-source,” “common-gate,” “transconductance,” “admittance,” and “impedance.” Those of ordinary skill in the art can recognize an inductor symbol and a capacitor symbol. Those of ordinary skill in the art can also readily recognize a symbol of a MOST (either NMOST or PMOST), and its associated “source,” “gate,” and “drain” terminals. Terms and basic concepts like these are apparent to those of ordinary skill in the art and thus will not be explained in detail here.

Those of ordinary skill in the art can read schematics comprising NMOST, PMOST, inductor, and capacitor, and do not need a detailed description of how one of them connects to another.

Throughout this disclosure, “DC” stands for direct current, and “AC” stands for alternating current. A DC node is a node of a substantially fixed electric potential. In particular, “V_{DD}” denotes a first DC node referred to as a power node, and “V_{SS}” denotes a second DC node referred to as a ground node.

A signal is a voltage of a variable level that carries certain information and can vary with time. The level of the signal at a moment represents the state of the signal at that moment. In this present disclosure, “signal” and “voltage” often refer to the same thing and thus are interchangeable.

Throughout this disclosure, differential signaling is widely used, wherein a signal comprises a first voltage and a second voltage denoted with suffixes “+” and “−,” respectively, attached in subscript, and the first voltage and the second voltage have the same DC component but opposite AC component. For instance, a signal V₁ in a differential signaling embodiment comprises two voltages V₁₊ and V₁₋, wherein V₁₊ and V₁₋ have the same DC component but opposite AC components.

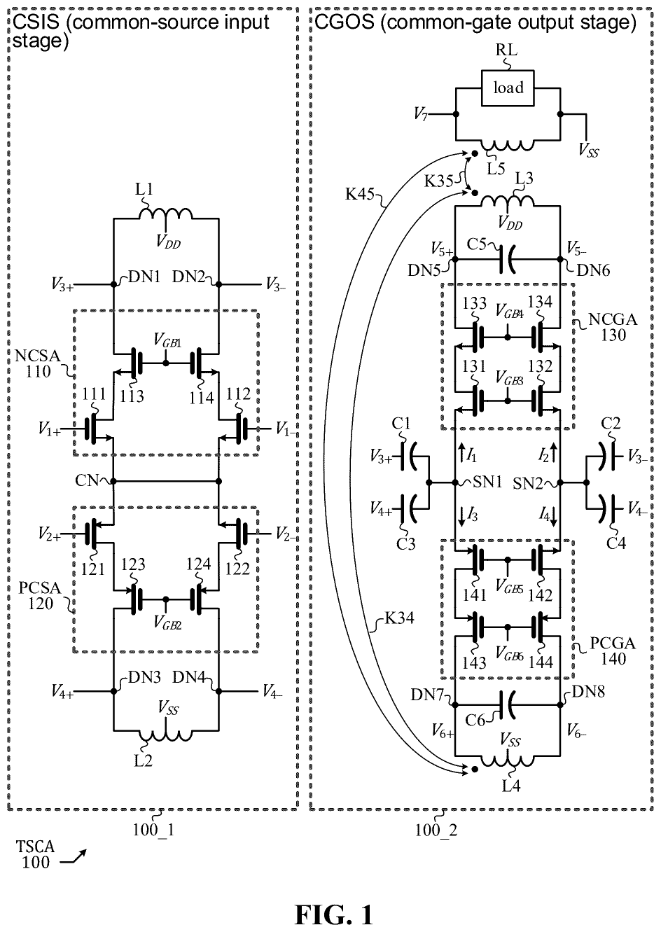

FIG. 1 depicts a schematic diagram of a two-stage complementary amplifier (TSCA) 100 in accordance with an embodiment of the present disclosure. The TSCA 100 comprises a common-source input stage (CSIS) 100_1 and a common-gate output stage (CGOS) 100_2. The CSIS 100_1 comprises a stack-up of a N-type common-source amplifier (NCSA) 110 and a P-type common-source amplifier (PCSA) 120, a first inductor L1, and a second inductor L2. The CGOS 100_2 comprises a stack-up of a N-type common-gate amplifier (NCGA) 130 and a P-type common-gate amplifier (PCGA) 140, four capacitors C1, C2, C3, and C4, a third inductor L3, a fourth inductor L4, a fifth inductor L5, and a load RL.

The NCSA 110 comprises four NMOSTs 111, 112, 113, and 114, receives a first signal V₁ (comprising V₁₊ and V₁₋ in a differential signal embodiment) and output a third signal V₃ (comprising V₃₊ at a first drain node DN1 and V₃₋ at a second drain node DN2 in a differential signal embodiment) across the first inductor L1 that is inserted between the first drain node DN1 and the second drain node DN2. NMOSTs 111 and 112 are configured in a common-source topology to convert V₃₊ and V₃₋ into currents output to NMOSTs 113 and 114, respectively, while NMOSTs 113 and 114 are configured in a cascode topology to direct the currents output from NMOSTs 111 and 112 to nodes DN1 and DN2, respectively. NMOSTs 113 and 114 are biased by a first gate bias voltage V_{GB1}. A center tap of L1 connects to a power supply node “V_{DD}.”

The PCSA 120 comprises four PMOSTs 121, 122, 123, and 124, receives a second signal V₂ (comprising V₂₊ and V₂₋ in a differential signal embodiment) and output a fourth signal V₄ (comprising V₄₊ at a third drain node DN3 and V₄₋ at a fourth drain node DN4 in a differential signal embodiment) across the second inductor L2 that is inserted between the third drain node DN3 and the fourth drain node DN4. PMOSTs 121 and 122 are configured in a common-source topology to convert V₂₊ and V₂₋ into currents output to PMOSTs 123 and 124, respectively, while PMOSTs 123 and 124 are configured in a cascode topology to direct the currents output from PMOSTs 121 and 122 to nodes DN3 and DN4, respectively. PMOSTs 123 and 124 are biased by a second gate bias voltage V_{GB2}. A center tap of L2 connects to a ground node “V_{SS}.”

In an embodiment, V₁₊, V₁₋, V₂₊, and V₂₋ can be mathematically modeled by the following equations:

$${V}_{1 +} = {V}_{BN} + {A}_{N} ( t ) sin ( ω t + {φ}_{N} ( t ) ) \qquad ( 1 )$$

$${V}_{1 -} = {V}_{BN} - {A}_{N} ( t ) sin ( ω t + {φ}_{N} ( t ) ) \qquad ( 2 )$$

$${V}_{2 +} = {V}_{BP} + {A}_{P} ( t ) sin ( ω t + {φ}_{P} ( t ) ) \qquad ( 3 )$$

$${V}_{2 -} = {V}_{BP} - {A}_{P} ( t ) sin ( ω t + {φ}_{N} ( t ) ) \qquad ( 4 )$$

Here, t is a time variable; ω is an angular frequency of an input signal; V_{BN} is a DC (direct current) level of V₁₊ and V₁₋; V_{BP} is a DC level of V₂₊ and V₂₋; A_{N}(t) and φ_{N}(t) are time-varying amplitude and phase, respectively, of the first signal V₁; and A_{P}(t) and φ_{P}(t) denote time-varying amplitude and phase, respectively, of the second signal V₂. In a preferred yet nonbinding embodiment, A_{N} (t) is the same as A_{P}(t), while φ_{N}(t) is the same as φ_{P}(t). V_{BN} and V_{BP} jointly determine a biasing condition of NMOSTs 111 and 112 and PMOSTs 121 and 122.

Both NCSA 110 and PCSA 120 are circuits well known in the prior art and therefore are not further explained in detail. However, when NCSA 110 is used in the prior art, the sources of NMOSTs 111 and 112 are usually connected to a low-side DC node (e.g., ground node) and thus are subject to source degeneration (due to nonzero impedance of the low-side DC node). Likewise, when PCSA 120 is used in the prior art, the sources of PMOSTs 121 and 122 are usually connected to a high-side DC node (e.g., power supply node) and thus are subject to source degeneration (due to nonzero impedance of the high-side DC node). In CSIS 100_1, however, sources of NMOSTs 111 and 112 and PMOSTs 121 and 122 are all connected to the same center node CN. Since both V₁ and V₂ are differential signals with opposite AC components, the voltage at the center node CN can remain substantially fixed despite the dynamic nature. The source degeneration and “ground bounce” or “power bounce” issue that commonly exists in the prior art are thus alleviated. Also, note that CSIS 100_1 belongs to an embodiment of a differential hybrid amplifier disclosed in U.S. Pat. No. 10,447,218 and therefore no further explanations are given here. Any tweak, such as adding “neutralization capacitors,” and/or “feedback capacitors,” and/or “cross-coupling capacitors” as disclosed therein can be applied to CSIS 100_1 at the discretion of circuit designers.

The NCGA 130 comprises four NMOSTs 131, 132, 133, and 134. NMOSTs 131 and 132 are configured in a common-gate topology, while NMOSTs 133 and 134 are configured in a cascode topology. NMOSTs 131 and 132 receive a first current I₁ and a second current I₂ from a first source node SN1 and a second source node SN2, and output currents to NMOSTs 133 and 134, respectively. NMOSTs 133 and 134 direct the currents output from NMOST 131 and NMOST 132 to a fifth drain node DN5 and a sixth drain node DN6 to establish a fifth signal V₅ comprising V₅₊ and V₅₋ at nodes DN5 and DN6, respectively. The third inductor L3 is inserted across DN5 and DN6. A center tap of L3 connects to the power supply node “V_{DD}.” NMOSTs 131 and 132 are biased by a third gate bias voltage V_{GB3}. NMOSTs 133 and 134 are biased by a fourth gate bias voltage V_{GB4}.

The PCGA 140 comprises four PMOSTs 141, 142, 143, and 144. PMOSTs 141 and 142 are configured in a common-gate topology, while PMOSTs 143 and 144 are configured in a cascode topology. PMOSTs 141 and 142 receive a third current I₃ and a fourth current I₄ from the first source node SN1 and the second source node SN2, and output currents to PMOSTs 143 and 144, respectively. PMOSTs 143 and 144 direct the currents output from PMOST 141 and PMOST 142 to a seventh drain node DN7 and an eighth drain node DN8 to establish a sixth signal V₆ comprising V₆₊ and V₆₋ at nodes DN7 and DN8, respectively. The fourth inductor L4 is inserted across DN7 and DN8. A center tap of L4 connects to the ground node “V_{SS}.” PMOSTs 141 and 142 are biased by a fifth gate bias voltage V_{GB5}. PMOSTs 143 and 144 are biased by a sixth gate bias voltage V_{GB6}.

In an optional embodiment, CGOS 100_2 further includes a fifth capacitor C5 inserted in parallel with L3 across DN5 and DN6 and a sixth capacitor C6 inserted in parallel with L4 across DN7 and DN8; this way, a resonance condition can be established to boost a gain and enlarge an amplitude of V₅ and V₆. The third gate bias voltage V_{GB3} and the fifth gate bias voltage V_{GB5} jointly determine a biasing condition of NMOSTs 131 and 132 and PMOSTs 141 and 142.

The three inductors L3, L4, and L5 are laid out in a way to have a very strong mutual coupling. That is, the mutual coupling K34 between L3 and L4, the mutual coupling K35 between L3 and L5, and the mutual coupling K45 between L4 and L5, are all very strong. Due to strong mutual coupling, L3, L4, and L5 can store magnetic energy more efficiently, and V₅ and V₆ can be coupled to establish a seventh signal V₇ at the load RL more efficiently.

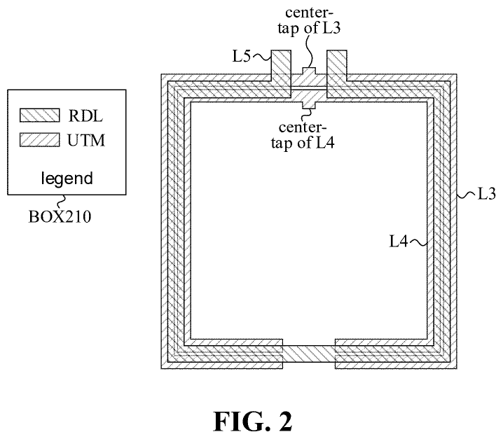

In an embodiment, by way of example but the limitation, the TSCA 100 is integrated and fabricated on a silicon substrate using a CMOS (complementary metal-oxide semiconductor) process technology in a multi-layer architecture comprising a plurality of metal layers including an ultra-thick metal (UTM) layer and a RDL (re-distribution) layer that is right on top of the UTM layer. A top view of an exemplary layout of L3, L4, and L5 is shown in FIG. 2. A legend is shown in BOX210. As shown, L3 and L4 are laid out in a concentric manner on the UTM layer, and parallel to one another with a tight spacing; this way, a very strong mutual coupling between L3 and L4 can be established. L5 is also laid out in a substantially concentric manner on the RDL layer on top of L3 and L4 and also substantially parallel to L3 and L4. This way, a very strong mutual coupling between L3 and L5 and between L4 and L5 can be established.

Both CSIS 100_1 and CGOS 100_2 are balanced differential circuits, and each can be divided into two halves that are substantially identical. That is, NMOST 111 (113) is identical to NMOST 112 (114), PMOST 121 (123) is identical to PMOST 122 (124), NMOST 131 (133) is identical to NMOST 132 (134), PMOST 141 (143) is identical to PMOST 142 (144), C1 (C3) is identical to C2 (C4). In an embodiment, C1 (C2) is identical to C3 (C4).

By way of example but not limitation: the ground node “V_{SS}” is of 0V; the power supply node “V_{DD}” is of 3V; NMOSTs 111, 112, 113, 114, 131, 132, 133, and 134 have approximately the same threshold voltage of 0.4V; PMOSTs 121, 122, 123, 124, 141, 142, 143, and 144 have approximately the same threshold voltage of 0.4V; V_{BN} is 2V; V_{BP} is 1V; V_{GB1} is 2.7V; V_{GB2} is 0.3V; V_{GB3} is 2V; V_{GB4} is 2.7V; V_{GB5} is 1V; and V_{GB6} is 0.3V. This way, all the transistors in TSCA 100 are biased in the saturation region.

In an embodiment, by way of limitation but not limitation, NMOST 111 (112) and PMOST 121 (122) are sized properly to have approximately the same transconductance gₘ₁. Likewise, NMOST 131 (132) and PMOST 141 (142) are sized properly to have the same transconductance gₘ₂. These can be well understood by those of ordinary skill in the art and thus not further explained.

In an embodiment, by way of example but not limitation, C1, C2, C3, and C4 have the same capacitance Cᵢ; L1 and L2 have the same inductance Lᵢ; and gₘ₂ is substantially larger than the admittance of C1, C2, C3, and C4, that it:

$${g}_{m 2} ≫ ω {C}_{i} \qquad ( 5 )$$

In other words, the impedance (i.e., 1/gₘ₂) looking into NMOST 131 (PMOST 141) and NMOST 132 (PMOST 142) from SN1 and SN2, respectively, is much smaller than the impedance of C1, C2, C3, and C4.

Lᵢ and Cᵢ are chosen such that L1 forms a resonance with C1 and C2, while L2 forms a resonance with C3 and C4. Mathematically, the resonance condition is satisfied if the following equation holds:

$$\frac{{ω}^{2} {L}_{i} {C}_{i}}{2} = 1 \qquad ( 6 )$$

At resonance, the reactance of L1 (L2) is approximately cancelled by the reactance of C1 (C3) and C2 (C4), but there remains a finite impedance seen by NCSA 110 and PCSA 120 due to impairments of intrinsic resistances of L1, L2, C1, C2, C3, and C4 and nonzero value of 1/gₘ₂. Among all, in an embodiment, the impairment of the nonzero value of 1/gₘ₂ dominates, and 1/gₘ₂ can be regarded as an ESR (equivalent series resistance) of each of capacitors C1, C2, C3, and C4. By applying serial-to-parallel transformation that is well understood by those of ordinary skills in the art, one can obtain that, the impedances looking from the drains of NMOSTs 113 and 114 and PMOSTs 123 and 124 into drain nodes DN1, DN2, DN3, and DN4, respectively, are all approximately

$$\frac{{g}_{m 2}}{{ω}^{2} {C}_{i}^{2}} .$$

By applying AC (alternate current) analysis, we can obtain the following expressions:

$${V}_{3 +} = {V}_{DD} - {G}_{N 1} {A}_{N} ( t ) sin ( ω t + {φ}_{N} ( t ) + {θ}_{N 1} ) \qquad ( 7 )$$

$${V}_{3 -} = {V}_{DD} + {G}_{N 1} {A}_{N} ( t ) sin ( ω t + {φ}_{N} ( t ) + {θ}_{N 1} ) \qquad ( 8 )$$

$${V}_{4 +} = {V}_{SS} - {G}_{P 1} {A}_{P} ( t ) sin ( ω t + {φ}_{P} ( t ) + {θ}_{P 1} ) \qquad ( 9 )$$

$${V}_{4 -} = {V}_{SS} + {G}_{P 1} {A}_{P} ( t ) sin ( ω t + {φ}_{P} ( t ) + {θ}_{P 1} ) \qquad ( 10 )$$

Here, G_{N1} is a gain of NCSA 110, G_{P1} is a gain of PCSA 120, θ_{N1} is a phase shift caused by NCSA 110, and θ_{P1} is a phase shift caused by PCSA 120. Also, G_{N1} (G_{P1}) is approximately equal to gₘ₁, which is the transconductance of NMOST 111 (PMOST 121), times

$$\frac{{g}_{m 2}}{{ω}^{2} {C}_{i}^{2}} ,$$

which is the impedance looking from NCSA 110 (PCSA 120) into drain node DN1 (DN3), and can be approximated by the following expressions:

$${G}_{N 1} \approx {G}_{P 1} \approx \frac{{g}_{m 1} {g}_{m 2}}{{ω}^{2} {C}_{i}^{2}} \qquad ( 11 )$$

In terms of AC analysis, I₁ is approximately the same as I₃ and is approximately equal to the AC component of V₃₊ times ωCᵢ, which is the admittance of C1, with a 90-degree phase shift, that is:

$${I}_{1} \approx - \frac{{g}_{m 1} {g}_{m 2}}{ω {c}_{i}} \cdot {A}_{N} ( t ) sin ( ω t + {φ}_{N} ( t ) + {θ}_{N 1} + \frac{π}{2} ) \qquad ( 12 )$$

Likewise, I₂ is approximately the same as I₄ and can be approximated by the following expression:

$${I}_{2} \approx - \frac{{g}_{m 1} {g}_{m 2}}{ω {c}_{i}} \cdot {A}_{N} ( t ) sin ( ω t + {φ}_{N} ( t ) + {θ}_{N 1} + \frac{π}{2} ) . \qquad ( 13 )$$

The above analysis is based on assuming NMOSTs 131 and 132, and PMOSTs 141 and 142 remain in the saturation region and thus present an impedance of 1/gₘ₂. However, as the amplitude of A_{N}(t) and A_{P}(t) increases, eventually NMOSTs 131 and 132, and PMOSTs 141 and 142 will enter into the triode region. Fortunately, when that happens, NMOSTs 131 and 132, and PMOSTs 141 and 142 will effectively become a resistor of a resistance that is also equal to 1/gₘ₂. In other words, the equations remain valid, even though the underlying physics and operation regions of NMOSTs 131 and 132 and PMOSTs 141 and 142 have changed. This way, high linearity can be achieved. Although eventually NMOSTs 111 and 112 and PMOSTs 121 and 122 will enter the triode region (as the amplitude of A_{N}(t) and A_{P}(t) increases), this is inevitable in any common-source amplifier circuit. However, in a two-stage common-source amplifier, the nonlinearity of the output stage will dominate the nonlinearity of the input stage, due to that the output stage receives a larger swing due to the amplification of the input stage. In TSCA 100, however, the linearity of the output stage can be greatly improved, due to that CGOS 100_2 can present substantially the same load to CSIS 1001 regardless of the amplitude of the input signal (i.e., A_{N}(t) and A_{P}(t)), and still can direct I₁, I₂, I₃, and I₄ to DN5, DN6, DN7, and DN8, respectively, in a linear manner despite NMOSTs 131, 132, 133, and 134 may enter into the triode region.

Note that equations (12) and (13) are used in a context of AC signal, and the DC components of I₁, I₂, I₃, and I₄ are omitted.

Those skilled in the art can choose to stack up additional transistors configured in a cascode topology to enhance reverse isolation or reduce the stress on transistors.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A two-stage complementary amplifier (TSCA) comprising:
a common-source input stage comprising a stack-up of a n-type common-source amplifier (NCSA) and a p-type common-source amplifier (PCSA) configured to receive a first signal and a second signal and output a third signal and a fourth signal across a first inductor and a second inductor, respectively;
a common-gate output stage comprising a stack-up of a n-type common-gate amplifier (NCGA) and a p-type common-gate amplifier (PCGA) configured to receive the third signal and the fourth signal via a first capacitor and a second capacitor, respectively, and output a fifth signal and a sixth signal across a third inductor and a fourth inductor, respectively; and
a fifth inductor terminated with a load, wherein the third inductor, the fourth inductor, and the fifth inductor are laid out tightly and substantially parallel to have strong mutual coupling.

2. The TSCA of claim 1, wherein: the NCSA comprises a stack-up of a first NMOST (n-channel metal-oxide semiconductor field-effect transistor) and a second NMOST; the first NMOST is configured in a common-source topology to receive the first signal from its gate and outputs a first internal current via its drain; and the second NMOST is configured in a cascode topology to direct the first internal current received from its source to the first inductor via its drain.

3. The TSCA of claim 2, wherein: the PCSA comprises a stack-up of a first PMOST (p-channel metal-oxide semiconductor field-effect transistor) and a second PMOST; the first PMOST is configured in a common-source topology to receive the second signal from its gate and outputs a second internal current via its drain; and the second PMOST is configured in a cascode topology to direct the second internal current received from its source to the second inductor via its drain.

4. The TSCA of claim 3, wherein a source of the first NMOST and a source of the first PMOST are directly connected.

5. The TSCA of claim 1, wherein: the NCGA comprises a stack-up of a first NMOST (n-channel metal-oxide semiconductor field-effect transistor) and a second NMOST; the first NMOST is configured in a common-gate topology to receive a first current from a source node via its source and outputs a first internal current via its drain; the second NMOST is configured in a cascode topology to direct the first internal current from its source to the third inductor via its drain; and the source node is coupled to the third signal and the fourth signal via the first capacitor and the second capacitor, respectively.

6. The TSCA of claim 5, wherein: the PCGA comprises a stack-up of a first PMOST (p-channel metal-oxide semiconductor field-effect transistor) and a second PMOST; the first PMOST is configured in a common-gate topology to receive a second source current from the source node via from its source and outputs a second internal current via its drain; the second PMOST is configured in a cascode topology to direct the second internal current from its source to the fourth inductor via its drain.

7. The TSCA of claim 6, wherein a transconductance of the first NMOST is substantially greater than an admittance of the first capacitor and an admittance of the second capacitor.

8. The TSCA of claim 6, wherein a transconductance of the first PMOST is substantially greater than an admittance of the first capacitor and an admittance of the second capacitor.

9. The TSCA of claim 1, wherein the first signal and the second signal have different DC (direct current) components but approximately the same AC (alternate current) component.

10. The TSCA of claim 1, wherein the first inductor and the first capacitor form a resonant network at a frequency approximately equal to a frequency of the first signal and the second signal.

11. The TSCA of claim 1, wherein the second inductor and the second capacitor form a resonant network at a frequency approximately equal to a frequency of the first signal and the second signal.

12. The TSCA of claim 1 further comprising a third capacitor inserted in parallel with the third inductor to form a resonance with the third inductor, and a fourth capacitor inserted in parallel with the fourth inductor to form a resonance with the fourth inductor.

13. The TSCA of claim 1, wherein a center tap of the first inductor connects to a power supply node, and a center tap of the second inductor connects to a ground node.

14. The TSCA of claim 1, wherein a center tap of the third inductor connects to a power supply node, and a center tap of the fourth inductor connects to a ground node.
